(19) United States
(12) Patent Application Publication
(10) Pub. No.: US 2018/0306872 A1
(43) Pub. Date: Oct. 25, 2018

(54) METHOD FOR LOCATING A MAGNETIC OBJECT

(71) Applicant: COMMISSARIAT A L'ENERGIE ATOMIQUE ET AUX ENERGIES AL TERNATIVES, Paris (FR)

(72) Inventors: Antoine VIANA, Herbeys (FR); Saifeddine ALOUI, Fontaine (FR)

(21) Appl. No.: 15/738,081

(22) PCT Filed: Jul. 8, 2016
(86) PCT No.: PCT/EP2016/066323

§ 371 Date: Dec. 19, 2017

(30) Foreign Application Priority Data
Jul. 9, 2015 (FR) 1556501

(51) Int. Cl. G01R 33/00; G01V 3/08

(52) U.S. Cl. CPC G01R 33/0064; G01V 3/081

(57) ABSTRACT

A method allowing the determination of the location and/or the orientation of a magnetic field source in space, and more particularly a method for determining the relative position in space of at least one magnetic field source in relation to at least one magnetic field sensor comprises the steps of acquiring measurements of the magnetic field, computing a solution of the expression of the magnetic field generated by at least one magnetic field source by modeling each magnetic field source by an element chosen from among a superposition of solenoids and a superposition of charged planes, then by estimating the value of a complete elliptic integral linked to the model by an algorithm using a Landen transformation and computing at least one element chosen from among the position and the orientation of each magnetic field source.

The invention relates to a method allowing the location and/or the orientation of a magnetic field source in space to be determined.

The devices for detecting movements in space through magnetic field sensors, or magnetometers, are generally composed of a series of magnetic field sensors, of one or more magnets and of one or more objects whose movements are to be detected.

A first method consists in detecting the magnetic field emitted by a fixed magnet. The movement of an object induces variations of the magnetic field which are detected by fixed sensors. These variations are then fitted to a model to deduce therefrom the movement of the object. In U.S. Pat. No. 4,785,242, a movement with one degree of freedom (rotation) is detected in this way.

A second method consists in securely linking the magnetic field sources and the objects to be detected. Yan, L. et al. present, in An Orientation Measurement Method Based on Hall-effect Sensors for Permanent Magnet Spherical Actuators with 3D Magnet Array (Scientific reports, 4, 2014), a method for detecting the rotation with three degrees of freedom of a rotor linked to permanent magnets. The magnetic field is detected by Hall-effect sensors, and the movement is computed by an adjustment of the data based on an exponential approximation.

One limitation in these detection methods stems from the difficulty in correlating the signals from the sensors with an analytical or numerical model of the magnetic field in three dimensions.

WO2013144342 discloses a method and a device for determining the location and the orientation of a magnetic object by using an array of triaxial magnetic field sensors, allowing the sensor to determine the direction and the amplitude of the magnetic induction at the measurement point. When the magnetic field has been measured by all or some of the sensors, the device implements a mathematical model associating each sensor measurement with the position and with the orientation of the magnetic field source in space. The model used performs an approximation of the magnetic field source by a magnetic dipole which is implemented in the form of a Kalman filter.

The use of a dipole model offers the advantage of being compatible with the feasible computation load of a standard processor. On the other hand, this model has a limited accuracy. In particular, it introduces significant errors if the magnetic source, of maximum dimension L, is situated at a distance less than 10 L from a magnetic field sensor. The error between the magnetic field measured by the sensor and the magnetic field according to a dipole model at the point of the sensor increases when the magnetic field source approaches the sensor, to diverge when the magnetic field source and the magnetic sensor tend toward the same point. The implementation of a model that takes account of the exact geometry of the magnetic field source would be advantageous to accurately compute the location and the orientation of a source close to a sensor, situated for example at a distance less than 10 L from a sensor, but may represent a computation load incompatible with the computation load that can be imposed on the processor for real-time processing of the data.

The aim of the invention is to overcome the abovementioned drawbacks of the prior art. More particularly, it aims to overcome the limitations of the dipole models while maintaining an acceptable level of computational complexity, in particular for real-time applications using a processor embedded in a portable device.

One object of the invention that allows this aim to be achieved is a method for determining the relative position in space of at least one magnetic field source in relation to at least one magnetic field sensor comprising the steps of:

a) acquiring measurements of the magnetic field generated by at least one said magnetic field source by means of at least one magnetic field sensor;

b) computing, by means of at least one processor, a solution of the expression of the magnetic field generated by at least one said magnetic field source by modeling each said magnetic field source by an element chosen from among a superposition of solenoids and a superposition of charged planes, then by estimating the value of a complete elliptic integral linked to said model by an algorithm using a Landen transformation;

c) computing at least one element chosen from among the position and the orientation of each said magnetic field source by using at least one method chosen from among:
a minimization of the cost between said measurements of said magnetic field sensors and said solutions computed in the step b);
a Bayesian filtering, at successive instants, of each said measurement of each said magnetic field sensor, said filtering being a function of each said solution computed in the step b).

Advantageously, a choice is made to use at least one said Bayesian filtering in the step c), said Bayesian filter being a Kalman filter.

Advantageously, at least one said magnetic field source is in motion in relation to at least one said magnetic field sensor and at least one element chosen from among the position and the orientation of at least one said magnetic field source and the position and the orientation of at least one said magnetic field sensor is computed from a Kalman filtering of said measurements of at least one said magnetic field sensor, said Kalman filtering being a function of each said computed solution, at each of said successive instants.

Advantageously, at least one said magnetic field source can be placed at less than ten centimeters from at least one said magnetic field source.

The invention relates also to a human/machine interface comprising at least one said magnetic field source, at least one said magnetic field sensor, and at least one processing unit, at least one processing unit being programmed appropriately to implement each step of a said method.

Advantageously, the human/machine interface comprises a plurality of said magnetic field sensors, in which the set of said magnetic field sensors is a non-planar array.

Advantageously, at least one said magnetic field source of said human/machine interface is chosen from among a single-layer solenoid and a solid cylindrical magnet.

Advantageously, the human/machine interface comprises at least two said magnetic field sources, at least one said magnetic field source being a solenoid, and one said processing unit of said interface is programmed to command a periodic emission of the intensity of the magnetic field of said solenoid at a different frequency from at least one other said magnetic field source.

Advantageously, at least one said magnetic field source of said interface is a permanent magnet composed of an alloy of elements chosen from among iron, vanadium, neodyme, boron, aluminum, nickel, titanium, copper, samarium and cobalt.

It will be recalled that, in the paramagnetic or diamagnetic materials, the vector H, measured in amperes per meter (A/m) and which is also called “magnetic field” in numerous works, is linked to the vector B, called magnetic induction, measured in Tesla (T), by the relationship B=μ(H)·H+Br, where Br is the remnant induction. Most of the developments which follow remain valid if addressing the field H instead of the field B in the zone of linearity between B and H.

The following description presents several exemplary embodiments of the device of the invention: these examples are nonlimiting on the scope of the invention. These exemplary embodiments present both the essential features of the invention and additional features linked to the embodiments considered. In the interests of clarity, the same elements will bear the same numerical references in the different figures.

The invention will be better understood and other advantages, details and features thereof will become apparent from the following explanatory description, given by way of example with reference to the attached drawings in which:

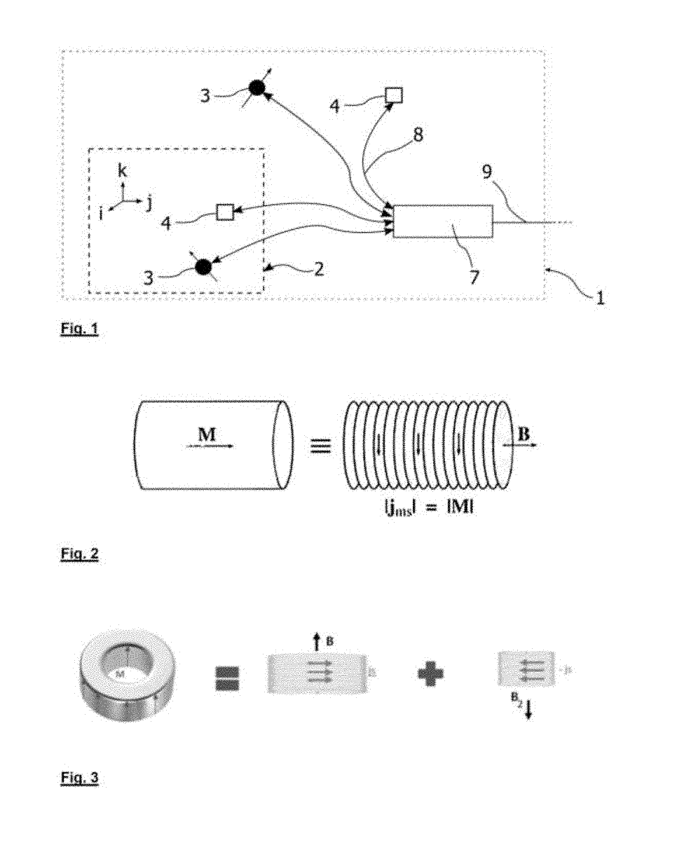

FIG. 1 presents a schematic view of the human/machine interface;

FIG. 2 presents the description of an amperian model of a magnetic field source;

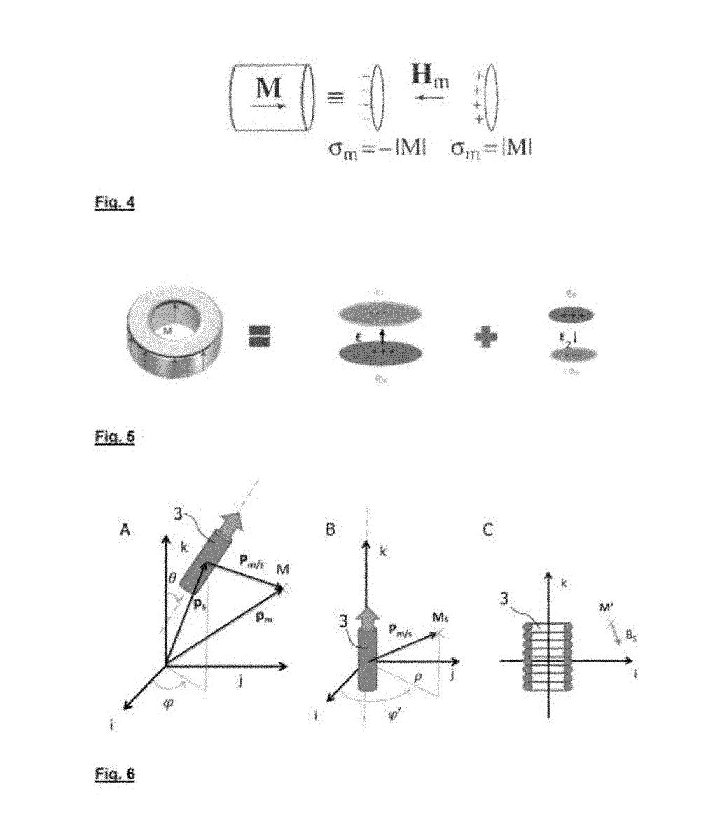

FIG. 3 illustrates the use of the superposition theorem in a modeling used in the invention;

FIG. 4 presents the description of a Coulombian model of a magnetic field source;

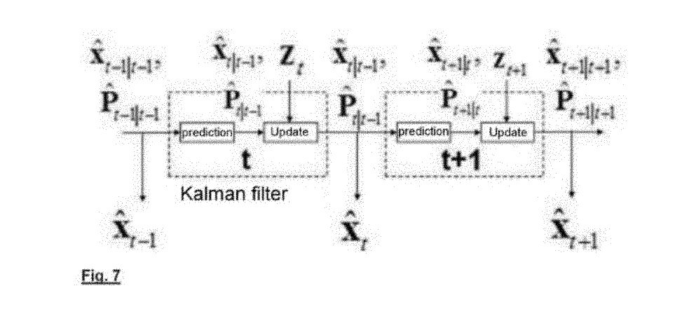

FIG. 5 illustrates the use of the superposition theorem in a modeling used in the invention;

FIG. 6 presents the implementation of the issue of computation of the magnetic field of a solenoid in a Cartesian reference frame;

FIG. 7 presents a schematic view of the operation of a Kalman filter.

Hereinafter in the text, the term magnetic field sensor is defined by a triaxial magnetic field sensor: the measurement of the magnetic field is performed on three different axes of space at the point of the magnetic field sensor.

FIG. 1 presents a schematic view of the human/machine interface 1. The human/machine interface 1 can comprise one or more magnetic field sources 3, one or more magnetic field sensors 4, each linked by a bus 8 to a processing unit 7. The bus 8 is represented in FIG. 1 by a double arrow; it can be produced by a wired or wireless data link. Each of the magnetic field sensors 4 and of the magnetic field sources 3 can be mechanically independent, or securely linked. In the particular embodiment illustrated by FIG. 1, the element of reference 2 comprises a magnetic field sensor 4 and a magnetic field source 3, securely linked and fixed in an orthogonal reference frame (i,j,k). In the embodiment illustrated by FIG. 1, one of the two magnetic field sources 3 does not belong to the element of reference 2 and can be moved freely in relation to the reference frame (i,j,k). Similarly, one of the two magnetic field sensors 4 does not belong to the element of reference 2 and can be moved freely in relation to the reference frame (i,j,k). To produce a human/machine interface 1, it is for example possible to securely link the element of reference 2 to a part of the human body, and link the magnetic field sensor 4 and the magnetic field source 3 not belonging to the element of reference 2 to other parts of the human body, in order to measure the respective movements thereof in relation to the reference frame (i,j,k).

In a particular embodiment of the invention, the magnetic field source 3 can be a permanent magnet, that is to say a magnet whose magnetic moment is non-nil in the absence of external magnetic field. The form of the magnetic field source 3 can be a solid cylinder or a holed cylinder. The magnetic field source 3 can be manufactured in an alloy of elements chosen from among iron, vanadium, neodyme, boron, aluminum, nickel, titanium, copper, samarium and cobalt.

In a particular embodiment of the invention, the magnetic field sensors 4 of one and the same element of reference 2, when the device uses a number greater than or equal to four thereof, are not coplanar. This arrangement makes it possible to obtain information on the magnetic field gradient for each of the axes defined in FIG. 1.

The magnetic field source 3 can also be a solenoid passed through by an alternating electrical current.

The human/machine interface 1 can comprise several magnetic field sources 3. In the case where several of these magnetic field sources 3 are solenoids passed through by alternating currents, it is possible to impose a frequency of variation of the electrical current particular to each of the solenoids, in order to differentiate the magnetic field sources 3 upon their detection.

More generally, in embodiments of the invention, the human/machine interface can comprise at least one field source 3 produced by a solenoid; the processing unit 7 can be programmed to command a periodic emission of the intensity of the magnetic field of said solenoid, at a different frequency from at least one other frequency of emission of the magnetic field of another magnetic field source 3. This feature makes it possible to distinguish the origin of the magnetic field received by the magnetic field sensor or sensors (4) by analyzing the different frequencies that make up one or more signals. It allows the simultaneous location of several magnetic field sources 3.

In another particular embodiment of the invention, the magnetic field source 3 is produced by the passage of electrical current in a single-layer solenoid.

The measurement element 2 can, in a particular embodiment of the invention, comprise an array of magnetic field sensors 4. The magnetic field sensors 4 can be placed in rows and in columns to form a matrix.

Each magnetic field sensor 4 can be fixed with no degree of freedom to the other magnetic field sensors 4. To this end, the magnetic field sensors 4 are fixed onto the top face of a rigid substrate. Each magnetic field sensor 4 measures the direction and the intensity of the magnetic field generated by one or more magnetic field sources 3 at the location of the sensor. For that, each magnetic field sensor 4 measures the norm of the orthogonal projection of the magnetic field generated by the magnetic field source or sources 3, at the location of this magnetic field sensor 4, on the three axes of this magnetic field sensor 4. In an exemplary embodiment, these three axes are mutually orthogonal. For example, a magnetic field sensor 4 will measure the components of the magnetic field on axes colinear to i, j and k.

Each magnetic field sensor 4 is connected to the processing unit 7 via an information transmission bus 8.

The processing unit 7 is capable of determining the position and/or the orientation of the field source or sources in the reference frame (i,j,k) of the measurement element 2 from the measurements of the magnetic field sensor or sensors 4. The processing unit 7 comprises, among other things, one or more processors and memories. The processor or processors are programmed to execute instructions stored in the memory or memories.

In particular, the processing unit 7 associates a mathematical model with all or some of the measurements of the magnetic field sensors 4 to deduce therefrom the position and/or the orientation of the magnetic field source or sources 3.

The processing unit 7 is also capable of restoring the location and/or the orientation of one or more magnetic field sources 3 to digital platforms via the output 9.

FIG. 2 presents the description of an amperian model of a magnetic field source 3. This model is used by the processing unit 7 of the invention to compute the position and/or the orientation of one or more magnetic field sources 3 as a function of the measurements performed by the magnetic field sensors 4.

Trémolet de Lacheisserie, É. (Magnétisme: Fondements, tome l de Collection Grenoble Sciences. [Magnetism: The Basics, volume 1 of Collection Grenoble Sciences.] EDP Sciences; 2000) demonstrates that induction B generated by the magnetized substance and/or by imposed electrical currents of density j₀, at any point of space, is reduced to a problem of electromagnetism of vacuum in which two types of currents are to be considered:
the real (or free) currents of volume density j₀
the currents associated with the magnetized substance (or linked currents), of volume density jₘ and surface density jₘₛ given by:

jₘ=rotM (1)

jₘₛ=M×n (2)

in which n is the unitary vector normal to the surface of the magnetized substance illustrated in FIG. 2 and oriented outward from the magnetic field source 3 and M is the magnetization at any point of the magnetized substance. This equivalence is called amperian model of the magnetization.

The relationship (1) indicates that, in the case of a uniform magnetization, jₘ=0. Thus, a uniformly magnetized cylinder is equivalent to a solenoid passed through by a surface current density |jₘₛ|=|M|.

FIG. 3 illustrates the use of the superposition theorem in a modeling used in the invention. In an exemplary embodiment of the invention, the magnetic field source 3 is a holed cylinder. The superposition theorem can be used by reducing the problem to the computation of the magnetic field generated by two nested solenoids (amperian model) passed through by opposing surface currents. The amperian model can be used by the processing unit 7 of the invention to compute the position and/or the orientation of one or more magnetic field sources 3 as a function of the measurements performed by the magnetic field sensors 4. The computation of the induction generated by the holed cylindrical magnet can be done by aggregating the inductions generated by the superposition of the magnetic inductions of the two solenoids presented in FIG. 3.

FIG. 4 presents a description of the coulombian model. This model can be used by the processing unit 7 of the invention, alternatively to the amperian model, to compute the position and the orientation of one or more magnetic field sources 3 as a function of the measurements performed by the magnetic field sensors 4. Trétmolet de Lacheisserie, É. (Magnétisme: Fondements, tome l de Collection Grenoble Sciences. [Magnetism: The Basics, volume 1 of Collection Grenoble Sciences] EDP Sciences, 2000) demonstrates that the magnetic field Hₘ produced by the magnetized substance is identical at all points of space to that created by hypothetical magnetic masses of volume ρₘ and surface σₘ densities given by:

ρₘ=−div M (3)

σₘ=M·n (4)

The magnetic field considered is, here, the magnetic field due to the substance (sometimes called demagnetizing field of the magnetized substance, and field of the substance outside of the magnetized substance). The magnetic induction B is obtained by taking into account the ambient magnetic field H₀ and the magnetization M by the relationship B=ρ₀(H₀+Hₘ+M). In the case of a magnet of FeNdB type, the ambient field, assumed to be of the order of the Earth's magnetic field in this embodiment of the invention, will be disregarded with respect to the remnant magnetization. When the magnetization is uniform, according to (3), ρₘ=0; the magnetization can be characterized by surface charge densities σₘ. For example, the field Hₘ created (in the substance and outside) by a cylinder uniformly magnetized along its axis is the same as that generated by two disks of uniform surface densities σₘ=±|M| situated on each of the planar faces of the cylinder.

FIG. 5 illustrates the use of the superposition theorem in a modeling used in the invention. In an exemplary embodiment of the invention, the magnetic field source 3 is a holed cylinder. The superposition theorem can be used by reducing the problem to the computation of the field generated by two pairs of uniformly charged disks (σₘ=±|M|, coulombian model).

Durand E. (Electrostatique et Magnétostatique, Tome l Les distributions [Electrostatics and Magnetostatics, Volume I: Distributions], Edition Masson et Cie, p. 246-250) has presented the computations of the magnetic inductions generated for hypothetical distributions of magnetic currents or masses, in particular for a solenoid passed through by a surface current jₘₛ. As described previously, a solenoid of main axis z passed through by a surface current jₛ is the amperian equivalent of a cylindrical permanent magnet of axis z, and of uniform magnetization M=|js|z. Thus, the knowledge of the magnetic induction generated at any point of space by a solenoid passed through by a surface current jₛ makes it possible to compute the magnetic induction generated at any point of space by a cylindrical magnet of uniform magnetization M=|js|z.

In cylindrical coordinates, the center of the reference frame being the geometrical center of the solenoid O, a point M being identified by its coordinates (r,θ,z), the induction produced at any point of space by the solenoid is independent of the variable θ because of the symmetry of the problem. The components Bᵣ and B_{z} are given by:

$$\begin{matrix}{B}_{r} = \frac{{μ}_{0} {j}_{s}}{2 π k} {\sqrt{\frac{a}{r}} [ ( {k}^{2} - 2 ) K ( {k}^{2} ) + 2 E ( {k}^{2} ) ]}_{{ξ}^{-}}^{{ξ}^{+}} & ( 5 ) \\ {B}_{z} = \frac{{μ}_{0} {j}_{s}}{4 π} \frac{1}{\sqrt{ar}} {zk [ K ( {k}^{2} ) + \frac{a - r}{a + r} Π ( {h}^{2} , {k}^{2} ) ]}_{{ξ}^{-}}^{{ξ}^{+}} & ( 6 ) \\ with \text{:} {k}^{2} = \frac{4 ar}{{( a + r )}^{2} + {z}^{2}} & ( 7 ) \\ {ξ}^{+ / -} = z \pm L / 2 & ( 8 )\end{matrix}$$

and K, E and Π the complete elliptic integrals of the first, second and third species:

$$\begin{matrix}K ( m ) = {\int }_{0}^{\frac{π}{2}} \frac{1}{\sqrt{1 - m {sin}^{2} θ}} d θ & ( 9 ) \\ E ( m ) = {\int }_{0}^{\frac{π}{2}} \sqrt{1 - m {sin}^{2} θ} d θ & ( 10 ) \\ Π ( n , m ) = {\int }_{0}^{\frac{π}{2}} \frac{1}{( 1 - n {sin}^{2} θ ) \sqrt{1 - m {sin}^{2} θ}} d θ & ( 11 )\end{matrix}$$

One of the features of the invention is combining the use of the amperian and/or coulombian models presented above with a resolution of the elliptical integrals (9), (10) and (11) by so-called Bulirsch algorithms (Bulirsch R., Numerical Calculation of Elliptic Integrals and Elliptic Functions, Numerische Mathematik 7, 78-90, 1965). These are iterative algorithms allowing the evaluation of common mathematical functions, in this case of the elliptical integrals, by using the fewest possible iterations.

An advantageous implementation of this algorithm, in terms of efficiency, is presented in Derby, N., & Olbert, S. (2010), “Cylindrical magnets and ideal solenoids”, American Journal of Physics, 78(3), 229-235. This implementation makes it possible to compute the function C (for Complete Elliptic Integral), defined by:

$$C ( {k}_{c} , p , c , s ) = {\int }_{0}^{\frac{π}{2}} \frac{c {cos}^{2} ϕ + s {sin}^{2} ϕ}{( {cos}^{2} ϕ + p {sin}^{2} ϕ ) \sqrt{{cos}^{2} ϕ + {k}_{c}^{2} {sin}^{2} ϕ}} d ϕ \qquad ( 12 )$$

It is then possible to rewrite the equations (5) and (6) according to the notations of Derby et al.:

$$\begin{matrix}{B}_{r} ( M ) = {B}_{0} [ {α}_{+} C ( {k}_{+} , 1 , 1 , - 1 ) - {α}_{-} C ( {k}_{-} , 1 , 1 , - 1 ) ] & ( 13 ) \\ {B}_{z} ( M ) = {B}_{0} \frac{a}{a + ρ} [ {β}_{+} C ( {k}_{+} , {γ}^{2} , 1 , γ ) - {β}_{-} C ( {k}_{-} , {γ}^{2} , 1 , γ ) ] & ( 14 ) \\ {B}_{0} = \frac{‖ {B}_{r} ‖}{π} = \frac{‖ {μ}_{0} m ‖}{π V} & ( 15 ) \\ {α}_{\pm } = \frac{a}{\sqrt{{z}_{\pm }^{2} + {( ρ + a )}^{2}}} & ( 16 ) \\ {β}_{\pm } = \frac{{z}_{\pm }}{\sqrt{{z}_{\pm }^{2} + {( ρ + a )}^{2}}} & ( 17 ) \\ γ = \frac{a - ρ}{a + ρ} & ( 18 ) \\ {k}_{\pm } = \sqrt{\frac{{z}_{\pm }^{2} + {( a - ρ )}^{2}}{{z}_{\pm }^{2} + {( a + ρ )}^{2}}} & ( 19 )\end{matrix}$$

The function C can be computed efficiently by using the Bulirsch algorithms, numerically translating a Landen transformation.

The Bulirsch publication considers three distinct cases. In the case of the computation of a complete integral of first species, which can be written in the form:

$$cel 1 ( {k}_{c} ) = {\int }_{0}^{∞} \frac{d ξ}{\sqrt{( 1 + {ξ}^{2} ) ( 1 + {k}_{c}^{2} {ξ}^{2} )}} \qquad ( 20 )$$

the algorithm translates a numerical integral computation using a Landen transformation. In the case of a complete integral of second species (including the case of the integrals of first species), which can be written in the form:

$$cel 2 ( {k}_{c} , a , b ) = {\int }_{0}^{∞} \frac{a + b {ξ}^{2}}{( 1 + {ξ}^{2} ) \sqrt{( 1 + {ξ}^{2} ) ( 1 + {k}_{c}^{2} {ξ}^{2} )}} d ξ \qquad ( 21 )$$

the algorithm also translates a numerical integral computation using a Landen transformation. It is also possible to note that, for a complex argument of the elliptic integral, the resolution of the elliptic integrals of first and second species use a Gauss transformation because the Landen transformation is not numerically stable in this case, but most of the embodiments of the invention use Landen transformations.

Finally, a third algorithm is proposed in the case of a complete elliptic integral of third specifies, that is to say of the form:

$$cel 2 ( {k}_{c} , m , p ) = {\int }_{0}^{∞} \frac{1 + {ξ}^{2}}{( 1 + p {ξ}^{2} ) \sqrt{( 1 + {ξ}^{2} ) ( 1 + {k}_{c}^{2} {ξ}^{2} )}} d ξ . \qquad ( 22 )$$

This third algorithm also translates a numerical integral computation using a Landen transformation (whereas the more general form, in the case of a non-complete elliptic integral is computed by using a Gauss transformation). In the embodiments of the invention, the computation of the integrals K(m), E(n) and Π(n,m) or C(k_{c}, p, c, s) corresponds to the computation of complete integrals: the embodiments of the invention use Landen transformations to advantageously compute these integrals.

The computation of the function C requires on average five iterations to converge to a first accuracy of 10⁻¹² which can make it possible to use this method to model, for example, the magnetic field generated by solenoids of different sizes without using the dipole approximation. The inventors have discovered that the use of this method for computing the magnetic field could make it possible to make the computation load acceptable for a standard processing unit, or a standard processor, while modeling the magnetic field at distances very close to the magnetic field source or sources. For example, in the case of a magnetic source of a characteristic dimension of a centimeter, an embodiment of the invention makes it possible to model the magnetic field, by virtue of the computation of the complete elliptic integrals by a Landen transformation, at a distance less than ten centimeters, which is impossible by using a dipole model of the magnetic field sources. When measuring the position and/or the relative orientation of a magnetic field source 3 in relation to a sensor 4, it is possible to bring the source 3 and the sensor 4 to within a distance less than 10 cm. In other embodiments of the invention, the modeling of the magnetic field 3 is done by a coulombian model. It is possible to compute equivalent complete elliptic integrals equivalent to K, E and Π by the Bulirsch algorithms.

FIG. 6 presents the implementation of the problem of computation of a magnetic field source 3 in a Cartesian reference frame. The panel A of FIG. 6 presents the generic configuration of the problem of computation of the magnetic field. The results of the expressions of the magnetic field obtained by a Bulirsch algorithm can be implemented to compute the coordinates of the magnetic induction B at any point M of space from the knowledge of parameters of the magnetic field source 3 (magnetic moment, dimensions and position).

The formulae (13) to (19) are expressed in the local cylindrical reference frame of the magnetic field source 3. FIG. 3 deals with the general case where the absolute reference frame is any.

To switch from the global reference frame ω(O,i,j,k) to a local reference frame linked to the solenoid S(S,i′,j′,k′), it is necessary to perform a translation and two rotations. The translation is performed with the vector pₛ then a rotation about the axis k makes it possible to place the solenoid in the plane (ik). Finally, a rotation about j makes it possible to straighten the solenoid such that its axis coincides with the axis k. The position of the point M in the reference frame S is given by Ms:

M_{S}=R_{y}(−θ)R_{z}(−φ)(OM−OS) (23)

The point M is described in the Cartesian reference frame linked to the magnetic source.

The panel B of FIG. 6 illustrates the alignment of the magnetic moment with the axis k. M can be placed on the plane (ik) by applying a rotation to M. There is then obtained the point M′ of coordinates (ρ,0,z) given by:

M′(ρ,0,z)=R_{z}(−φ′)M_{S} (24)

The effect of this rotation is presented by the panel C of FIG. 6. Once ρ and z are computed, it is possible to use (16) and (17) to compute the magnetic field at the point projected onto (ik). Once the magnetic field is computed, it is possible to perform the reverse rotations in order to determine the magnetic induction B_{w} in the initial reference frame:

B_{ω}=R_{z}(φ)R_{y}(φ)R_{z}(φ′)(B_{ρ},0,B_{z}) (25)

In embodiments of the invention, the rotation matrices are generated by geometrical operations not involving trigonometric functions of arc cosine or arc tangent type for reasons of numerical stability and speed of material hardware execution.

It is advantageously possible to use a second method for switching from the global reference frame w to the local reference frame S linked to the magnetic field source 3. P_{m/s}=OM−OS is used to define the relative position of the measurement point M in relation to the center of the solenoid S. The vector M is defined as the moment of the magnetic field source 3 (colinear to the axis of the magnetic field source 3). The normalized moment of the magnetic field source 3 is defined by Mₙ=M/∥M∥. The unitary vector from S to M is defined by P_{m/s,n}=P_{m/s}/∥P∥. In the cylindrical reference frame linked to the magnetic field source 3, the coordinates of the point M are (x,y,z)=(0,0,P·Mₙ). The magnetic induction vector B_{ω} in the global reference frame ω is then defined after the computation of the magnetic induction vector B_{S} in the local reference frame S by B_{ω}=B_{S}·Mₙ+B_{S}·(Mₙ×P_{m/s,n}×Mₙ).

The invention uses estimation methods which use, on the one hand, the analytical models of induction introduced previously, and, on the other hand, measurements from sensors. The combined use of these methods then makes it possible to compute the relative positions and/or orientations of one or more magnetic field source(s) 3 in relation to one or more magnetic field sensors 4. It can also be used to estimate the position and/or the orientation of one or more magnetic sensors 4 in relation to one or more magnetic field sources 3.

In the embodiments of the invention, a step occurs after the acquisition of the measurements from the magnetic field sensor or sensors 4 and after the computation by the processor unit 7 of the expression of the magnetic field 3 generated by at least one magnetic field source 3 by modeling the sources 3 by a superposition of solenoids and/or a superposition of uniformly charged planes, as described previously. This step consists in estimating the location and/or the orientation of a magnetic field source 3 and/or of a magnetic field sensor 4 according to a method chosen between an optimization, a Bayesian filtering or a method that is a hybrid of an optimization and a Bayesian filtering.

In the case of the optimization, the aim is to find a vector of parameters x (for example the position and/or the orientation of the magnetic field source 3, the magnetic moment of the magnetic field source 3, or the position and/or the orientation of the magnetic field sensor 4) which minimize a given cost. In this case, the optimization consists in minimizing the costs between the measurements of said sensors and the solutions computed in the modeling of the magnetic field. For example, it is possible to use the least squares method:

x=argminₓ((z−h(x))^{T}(z−h(x))) (26)

Here z is the measurement performed by the magnetic field sensor or sensors 4. h(x)=B_{ω}(x) is the model proposed in the preceding section. To resolve this problem, it is for example possible to use the Gauss-Newton method or the Levenberg-Marquardt method.

In the case of the Bayesian filter, it is possible to use the 1st order Markovienne approximation to estimate the position of one or more magnetic field sources 3 in relation to the magnetic field sensor(s) or vice-versa. This operation can be performed in two steps:
a prediction using the state at the preceding instant using a dynamic model of state evolution to predict the current state,
an update based on the innovation supported by the measurements given by the magnetic field sensors 4 in relation to the predicted measurements, computed on the basis of the amperian model explained previously.

Generally, to estimate the a posteriori state from an a priori state and from a measurement, the Bayes' theorem can be used:

$$P ( {x}_{t + 1} \vert {z}_{1 : t + 1} ) = \frac{P ( {z}_{t + 1} \vert {x}_{t + 1} , {z}_{1 : t} ) P ( {x}_{t + 1} \vert {z}_{1 : t} )}{P ( {z}_{t + 1} \vert {z}_{1 : t} )} = \frac{likelihood \times a priori}{evidence} \qquad ( 27 )$$

The computation of the likelihood involves a function h which links the state to the measurement. Here, the state is the position and/or the orientation of the magnetic source and the measurement is the magnetic field measured by the magnetic field sensor or sensors 4. This principle applies to all the Bayesian estimators. In particular, a Kalman filter can be used to resolve this problem. In this computation, it is possible to estimate the magnetic moment vector instead of the orientation to eliminate certain trigonometric computations.

FIG. 7 presents a schematic view of the operation of a Kalman filter. The Kalman filter makes it possible to find the state at the instant t+1 as a function of the state at the preceding instant in two operations (prediction and update). In particular in the case where a nonlinear measurement function is used (such as the case of the proposed model), it is possible to use the extended version of the filter.

In a Kalman filter, the state is described by the first two moments of its probability distribution. Since the latter is assumed Gaussian, the two moments are sufficient to describe it completely. The expectation of the state is called x̅ₜ₊₁ and its covariance matrix is called Pₜ₊₁.

A Kalman filter is said to be extended if it reuses the same equations used in a conventional Kalman filter by locally linearizing the measurement function:

h(xₜ₊₁)=Hₜ₊₁xₜ₊₁ (28)

The function is computed from (25). Hₜ₊₁ is the jacobian matrix evaluated at x̅_{t+1|t}. The prediction phase for a model of steady-state evolution is:

x̅_{t+1|t}=Fx̅_{t|t}

P_{t+1|t}=FP_{t|t}F^{T}+Qₜ (29)

where F is an identity matrix and Q is the covariance matrix of the state noise. It describes the uncertainty on the evolution of the state. The update phase makes it possible to use the proposed model to correct the prediction on the basis of the information provided by the current measurement, called innovation \tilde{y}ₜ₊₁. The following applies:

x̅_{t+1|t+1}=x̅_{t+1|t}+Kₜ₊₁\tilde{y}ₜ₊₁

P_{t+1|t+1}=P_{t+1|t}−Kₜ₊₁Hₜ₊₁P_{t+1|t} (30)

Here, Hₜ₊₁=∇ₓ[h(xₜ₊₁)] is the jacobian matrix of the measurement function h evaluated at x̅_{t+1|t}. Kₜ₊₁ is the Kalman gain. The innovation and the Kalman gain are computed as follows:

\tilde{y}ₜ₊₁=zₜ₊₁−h(x̅_{t+1|t}) (31)

Kₜ₊₁=P_{t+1|t}Hₜ₊₁^{T}Σ_{\tilde{y}}_{ₜ₊₁}_{\tilde{y}}_{ₜ₊₁}⁻¹ (32)

Σ_{\tilde{y}}_{ₜ₊₁}_{\tilde{y}}_{ₜ₊₁}⁻¹=Hₜ₊₁P_{t+1|t}Hₜ₊₁^{T}+Rₜ₊₁ (33)

In embodiments of the invention, the position and/or the relative orientation of a field source 3 in relation to the position and/or the orientation of a sensor 4 are computed from a Kalman filtering as described previously. The same principle applies for the Kalman filter of UKF type, as well as the particle filters and all the other Bayesian filters.

It is advantageously possible to use an algorithm called LMA (described in Aloui, S., Villien, C., & Lesecq, S. (2014), “A new approach for motion capture using magnetic field: models, algorithms and first results.” International Journal of Adaptive Control and Signal Processing) in place of the Kalman filter. This approach is based on the use of a hybrid Bayesian/optimization algorithm of Levenberg-Marquard type. When using the LMA algorithm, a prediction step is initially performed, similar to the prediction step described previously when using a Kalman filter. Secondly, an update step is performed, similar to the Kalman method described previously, but by replacing the cost optimization equations with:

$${x}_{t + 1 \vert t + 1} = arg min ( {[ \begin{matrix}{z}_{t + 1} - h ( {x}_{t + 1 \vert t + 1} ) \\ {x}_{t + 1 \vert t} - {x}_{t + 1 \vert t + 1}\end{matrix} ]}^{T} [ \begin{matrix}{R}_{t + 1}^{- 1} & 0 \\ 0 & {P}_{t + 1 \vert t}^{- 1}\end{matrix} ] [ \begin{matrix}{z}_{t + 1} - h ( {x}_{t + 1 \vert t + 1} ) \\ {x}_{t + 1 \vert t} - {x}_{t + 1 \vert t + 1}\end{matrix} ] ) \qquad ( 34 )$$

Each iteration i∈{1 . . . nᵢ} is computed by:

x_{t+1|t+1}ⁱ=x_{t+1|t+1}ⁱ⁻¹+Δ_{t+1|t+1}ⁱ⁻¹ (35)

in which:

Δ_{t+1|t+1}ⁱ⁻¹=[(P_{t+1|t+1}ⁱ⁻¹)⁻¹+λⁱdiag((P_{t+1|t+1}ⁱ⁻¹)⁻¹)]⁻¹eⁱ⁻¹ (36)

and:

eⁱ⁻¹=[(Hₜ₊₁ⁱ⁻¹)^{T}Rₜ₊₁⁻¹(zₜ−h(x_{t+1|t+1}ⁱ⁻¹))+(P_{t+1|t})⁻¹(x_{t+1|t}−x_{t+1|t-1}ⁱ⁻¹)] (37)

(P_{t+1|t+1}ⁱ⁻¹)⁻¹=Hₜ₊₁^{i-1T}Rₜ₊₁⁻¹Hₜ₊₁ⁱ⁻¹+(P_{t+1|t)}⁻¹ (38)

where λ is the damping factor, non-constant. The damping factor is initialized at λ⁰=1. For each iteration i, the error eⁱ=∥eⁱ∥₂ is computed. If eⁱ>eⁱ⁻¹, x_{t+1| t}ⁱ is left as such and λ is reduced (for example λⁱ⁺¹=λⁱ/10). Otherwise, x_{t+1|t}ⁱ is rejected (x_{t+1|t}ⁱ=x_{t+1|t}ⁱ⁻¹) and λ is increased (for example λⁱ⁺¹=10λⁱ).

The covariance matrix of the a posteriori estimated distribution is P_{t+1|t+1}=P_{t+1|t+1}ⁿ^{ᵢ}. It is computed as in the preceding example of the Kalman filter. This method makes the computation converge toward the Cramér-Rao (minimum bound of the estimation error).

1. A method for determining the relative position in space of at least one magnetic field source in relation to at least one magnetic field sensor comprising the steps of:
a) acquiring measurements of the magnetic field generated by at least one said magnetic field source by means of at least one magnetic field sensor;
b) computing, by means of at least one processor, a solution of the expression of the magnetic field generated by at least one said magnetic field source by modeling each said magnetic field source by an element chosen from among a superposition of solenoids and a superposition of charged planes, then by estimating the value of a complete elliptic integral linked to said model by an iterative Bulirsch algorithm using a Landen transformation;
c) computing at least one element chosen from among the position and the orientation of each said magnetic field source by using at least one method chosen from among:
a minimization of the cost between said measurements of said magnetic field sensors and said solutions computed in the step b);
a Bayesian filtering, at successive instants, of each said measurement of each said magnetic field sensor, said filtering being a function of each said solution computed in the step b).

2. The method as claimed in claim 1, wherein at least the Bayesian filtering is chosen as method for the step c), said Bayesian filter being a Kalman filter.

3. The method as claimed in claim 1, wherein at least one said magnetic field source is in motion in relation to at least one said magnetic field sensor and wherein at least one element chosen from among the position and the orientation of at least one said magnetic field source and the position and the orientation of at least one said magnetic field sensor is computed from a Kalman filtering of said measurements of at least one said magnetic field sensor, said Kalman filtering being a function of each said computed solution, at each of said successive instants.

4. The method as claimed in claim 1, wherein at least one said magnetic field source can be placed at less than ten centimeters from at least one said magnetic field sensor.

5. A human/machine interface comprising at least one magnetic field source, at least one magnetic field sensor, and at least one processing unit programmed appropriately to implement each step of claim 1.

6. The human/machine interface as claimed in claim 5, comprising a plurality of magnetic field sensors forming overall a non-planar array.

7. The human/machine interface as claimed in claim 5, wherein at least one said magnetic field source is chosen from among a single-layer solenoid and a solid cylindrical magnet.

8. The human/machine interface as claimed in claim 5, comprising at least two magnetic field sources, wherein at least one of said magnetic field sources is a solenoid, and wherein the processing unit is programmed to command a periodic emission of the intensity of the magnetic field of said solenoid at a different frequency from at least one other of said magnetic field sources.

9. The human/machine interface as claimed in claim 5, wherein at least one said magnetic field source is a permanent magnet composed of an alloy of elements chosen from among iron, vanadium, neodyme, boron, aluminum, nickel, titanium, copper, samarium and cobalt.
